(19) United States
(12) Patent Application Publication
(10) Pub. No.: US 2026/0173390 A1
(43) Pub. Date: Jun. 18, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Wonjin KIM, Suwon-si (KR); Joonyoung KWON, Suwon-si (KR); Junhyoung KIM, Suwon-si (KR); Jiyoung KIM, Suwon-si (KR); Sukkang SUNG, Suwon-si (KR); ByungChul LEE, Suwon-si (KR)

(21) Appl. No.: 19/389,147

(22) Filed: Nov. 14, 2025

(30) Foreign Application Priority Data
Dec. 18, 2024 (KR) 10-2024-0190547

(51) Int. Cl. H10B 43/40; H01L 23/00; H01L 25/065; H01L 25/18; H10B 80/00

(52) U.S. Cl. CPC H10B 43/40; H10B 80/00; H10W 90/00; H10W 90/792

(57) ABSTRACT

A semiconductor memory device includes a cell structure including a cell wiring structure and a cell bonding pad, and a peripheral circuit structure including a peripheral circuit substrate including a first surface and a second surface, a plurality of peripheral circuit elements disposed on the first surface of the peripheral circuit substrate, a peripheral wiring structure electrically connected to the plurality of peripheral circuit elements, and a peripheral bonding pad electrically connected to the peripheral wiring structure and in contact with the cell bonding pad, in which the plurality of peripheral circuit elements includes a plurality of first peripheral circuit elements in a first region of the peripheral circuit substrate and a plurality of second peripheral circuit elements in a second region, a thickness of the second region being greater than a thickness of the first region, the first surface of the peripheral circuit substrate extending in a second direction.

### CROSS-REFERENCE TO RELATED APPLICATION

This application claims priority to Korean Patent Application No. 10-2024-0190547, filed in the Korean Intellectual Property Office on Dec. 18, 2024, the entire contents of which are hereby incorporated by reference.

### BACKGROUND

### Technical Field

The present disclosure relates to a semiconductor memory device and an electronic system including the same.

### Description of Related Art

There is a need for a semiconductor memory device capable of storing high-capacity data in an electronic system that requires data storage. Accordingly, research is being conducted to increase the data storage capacity of the semiconductor memory device. For example, as one of the methods for increasing the data storage capacity of the semiconductor memory device, a semiconductor memory device has been proposed, which includes three-dimensional arrangement of memory cells instead of two-dimensional arrangement of memory cells.

### SUMMARY

To address one or more problems (e.g., the problems described above and/or other problems not explicitly described herein), the present disclosure provides a semiconductor memory device with improved electrical characteristics and an electronic system including the same.

To address one or more problems (e.g., the problems described above and/or other problems not explicitly described herein), the present disclosure provides a semiconductor memory device with improved integration density and an electronic system including the same.

According to some embodiments, a semiconductor memory device may include a cell structure including a cell wiring structure and a cell bonding pad electrically connected to the cell wiring structure, and a peripheral circuit structure including a peripheral circuit substrate including a first surface and a second surface facing the first surface, a plurality of peripheral circuit elements disposed on the first surface of the peripheral circuit substrate, a peripheral wiring structure electrically connected to the plurality of peripheral circuit elements, and a peripheral bonding pad electrically connected to the peripheral wiring structure and in contact with the cell bonding pad, in which the plurality of peripheral circuit elements may include a plurality of first peripheral circuit elements disposed in a first region of the peripheral circuit substrate and a plurality of second peripheral circuit elements disposed in a second region of the peripheral circuit substrate, a thickness of the second region of the peripheral circuit substrate may be greater than a thickness of the first region of the peripheral circuit substrate in a first direction, the first surface of the peripheral circuit substrate extends in a second direction, and the first direction intersects the second direction.

According to some embodiments, a semiconductor memory device may include a cell structure including a cell wiring structure and a cell bonding pad electrically connected to the cell wiring structure, and a peripheral circuit structure stacked on an upper surface of the cell structure in a first direction, in which the peripheral circuit structure may include a peripheral circuit substrate with a first surface and a second surface opposite to the first surface, the peripheral circuit substrate including a first region and a second region disposed in a second direction intersecting the first direction, a first peripheral circuit element disposed on the first region and a second peripheral circuit element disposed on the second region, a peripheral wiring structure electrically connected to the first peripheral circuit element and the second peripheral circuit element, and a peripheral bonding pad electrically connected to the peripheral wiring structure and contacting the cell bonding pad, and a first surface of the first region and a first surface of the second region may be coplanar with each other, and a second surface of the second region may be positioned at a higher level in the first direction than a second surface of the first region.

According to some embodiments, an electronic system may include a main substrate, a semiconductor memory device stacked on the main substrate, and a controller on the main substrate, which is electrically connected to the semiconductor memory device, in which the semiconductor memory device may include a cell structure including a cell wiring structure and a cell bonding pad electrically connected to the cell wiring structure, and a peripheral circuit structure including a peripheral circuit substrate including a first surface and a second surface facing the first surface, a plurality of peripheral circuit elements disposed on the first surface of the peripheral circuit substrate, a peripheral wiring structure electrically connected to the plurality of peripheral circuit elements, and a peripheral bonding pad electrically connected to the peripheral wiring structure and in contact with the cell bonding pad, in which the plurality of peripheral circuit elements may include a plurality of first peripheral circuit elements to which a first voltage is applied and a plurality of second peripheral circuit elements to which a second voltage higher than the first voltage is applied, the peripheral circuit substrate may include a first region in which the plurality of first peripheral circuit elements is disposed and a second region in which the plurality of second peripheral circuit elements is disposed, a thickness of the second region of the peripheral circuit substrate may be greater than a thickness of the first region of the peripheral circuit substrate based on a first direction, the first surface of the peripheral circuit substrate extends in a second direction, and the first direction intersects the second direction.

According to some embodiments of the present disclosure, the semiconductor memory device can have improved electrical performance and higher integration density because the body thickness of the transistors to which relatively low voltages are applied is reduced.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a plan view provided to explain a semiconductor memory device according to some embodiments;

FIG. 2 is a cross-sectional view taken along line X-X′ of FIG. 1;

FIG. 3 is an enlarged view of a boxed area B of FIG. 2;

FIG. 4 is a diagram provided to explain a semiconductor memory device according to some embodiments;

FIG. 5 is an enlarged view of a boxed area B of FIG. 4;

FIG. 6 is a diagram provided to explain a semiconductor memory device according to some embodiments;

FIG. 7 is an enlarged view of a boxed area C of FIG. 6;

FIG. 8 is a diagram provided to explain a semiconductor memory device according to some embodiments;

FIG. 9 is a diagram provided to explain a semiconductor memory device according to some embodiments;

FIGS. 10 to 12 are diagrams provided to explain a method for manufacturing a semiconductor memory device according to some embodiments;

FIGS. 13 to 15 are diagrams provided to explain a method for manufacturing a semiconductor memory device according to some embodiments;

FIG. 16 is an example block diagram provided to explain an electronic system according to some embodiments;

FIG. 17 is an example perspective view illustrating an electronic system including a semiconductor memory device according to some embodiments; and

FIG. 18 is a schematic cross-sectional view taken along line V-V′ of FIG. 17.

### DETAILED DESCRIPTION

Hereinbelow, a semiconductor memory device and an electronic system according to some embodiments of the present disclosure will be described in detail with reference to the drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes.

It will be understood that when an element is referred to as being “connected” or “coupled” to or “on” another element, it can be directly connected or coupled to or on the other element or intervening elements may be present. In contrast, when an element is referred to as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

Spatially relative terms, such as “below,” “lower,” “upper,” “front side”, “back side”, “right”, “left”, and the like, may be used herein for ease of description to describe positional relationships, such as illustrated in the figures, for example. It will be understood that the spatially relative terms encompass different orientations of the device in addition to the orientation depicted in the figures.

As used herein the terms “overlap”, “cover” or “covering” are intended to mean that an element is over another element. The elements may be touching or not. An element “covering” another element need not cover an entire element to be considered “covering”. The terms are intended to encompass one element “covering” all, or any part of, an element below it. As used herein, the word “surround” is intended to mean that an element is outside the other element. The elements may be touching or not. The surrounding element may or may not completely surround an inner element.

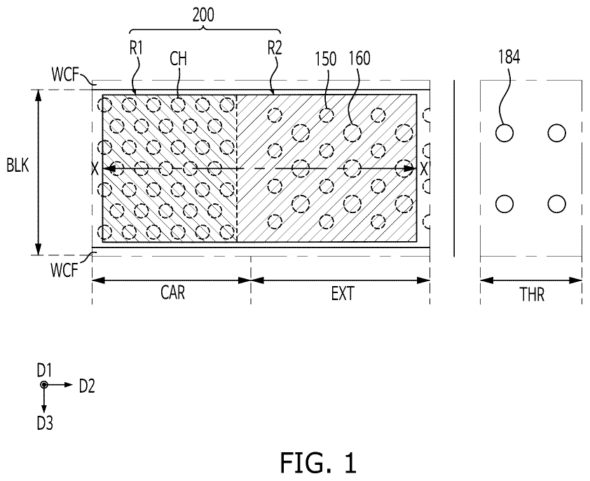

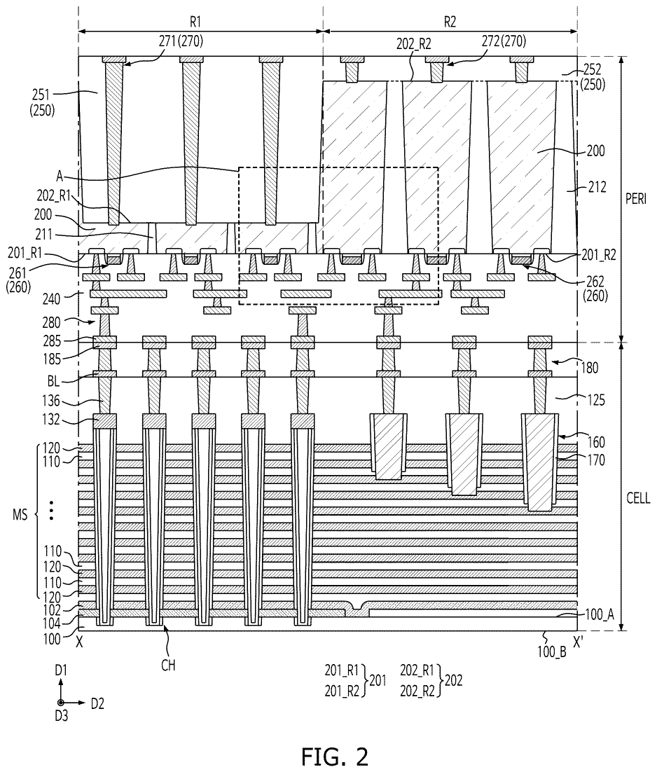

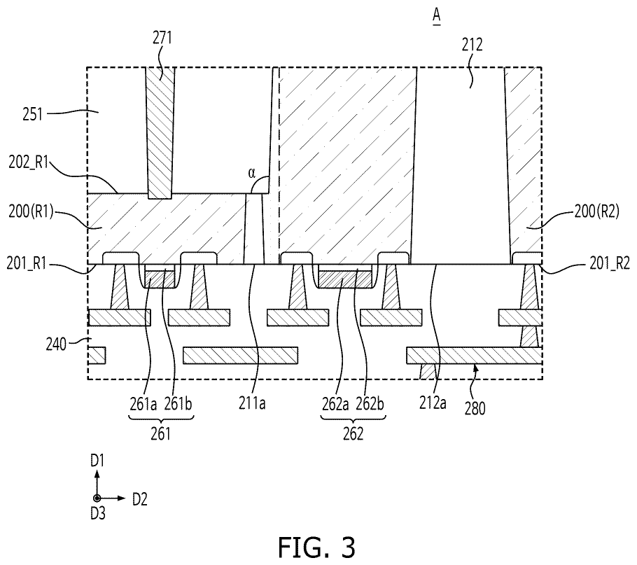

FIG. 1 is a plan view provided to explain a semiconductor memory device according to some embodiments. FIG. 2 is a cross-sectional view taken along line X-X′ of FIG. 1. FIG. 3 is an enlarged view of a boxed area B of FIG. 2.

The semiconductor memory device may be a semiconductor chip (i.e., a semiconductor device singulated from (e.g., cut from) a wafer).

The semiconductor memory device according to some embodiments may have a chip-to-chip (C2C) structure in which a peripheral circuit structure PERI and a cell structure CELL are connected to each other. For example, the semiconductor memory device may include a structure that connects a first chip including the cell structure CELL on a first wafer and a second chip including an upper peripheral circuit structure PERI on a second wafer, to each other through a bonding method. For example, the bonding method may be a hybrid bonding method.

Referring to FIGS. 1 and 2, the semiconductor memory device according to some embodiments may include the peripheral circuit structure PERI and the cell structure CELL.

The cell structure CELL may include a cell substrate 100, a source structure 102 and 104, a mold structure MS, a channel structure CH, a bit line BL, a word line contact 160, a contact spacer 170, a cell wiring structure 180, a cell bonding pad 185, etc.

The cell substrate 100 may include a cell array region CAR, an extension region EXT, and a through region THR.

A memory cell array including a plurality of memory cells may be formed on the cell array region CAR. The channel structure CH, the mold structure MS, the bit line BL, etc. may be disposed on the cell array region CAR. In the present disclosure, the expression that configuration B is formed or disposed on configuration A is not limited to that the configuration B is formed or disposed in contact with the configuration A. For example, it may also include an embodiment in which another configuration C is interposed between the configuration B and the configuration A. In addition, in the present disclosure, the expression that configuration B is formed or placed on configuration A is not limited to that the configuration B is disposed above the configuration A in the drawing. For example, it may also include an embodiment in which the configuration B is disposed below, or to the right or left side of the configuration A in the drawing.

The extension region EXT may be disposed around the cell array region CAR. For example, the extension region EXT may surround the cell array region CAR. The word line contact 160, the contact spacer 170, a dummy channel structure 150, etc. may be disposed on the extension region EXT.

The through region THR may be disposed outside the extension region EXT. For example, the through region THR may be disposed on one side of the extension region EXT, but embodiments are not limited thereto. A source contact 184, an input and output contact, etc. may be disposed in the through region THR.

For example, the cell substrate 100 may include a semiconductor substrate such as a silicon substrate, a germanium substrate, or a silicon-germanium substrate. Alternatively, the cell substrate 100 may include a Silicon-On-Insulator (SOI) substrate, a Germanium-On-Insulator (GOI) substrate, etc. In some embodiments, the cell substrate 100 may include polysilicon (poly Si).

The cell substrate 100 may include a first surface 100_A and a second surface 100_B opposite to the first surface 100_A. The first surface 100_A of the cell substrate 100 may refer to a surface on which the mold structure MS and the channel structure CH are disposed. The first surface 100_A of the cell substrate 100 may be referred to as a front side of the cell substrate 100. The second surface 100_B of the cell substrate 100 may be referred to as a back side of the cell substrate 100.

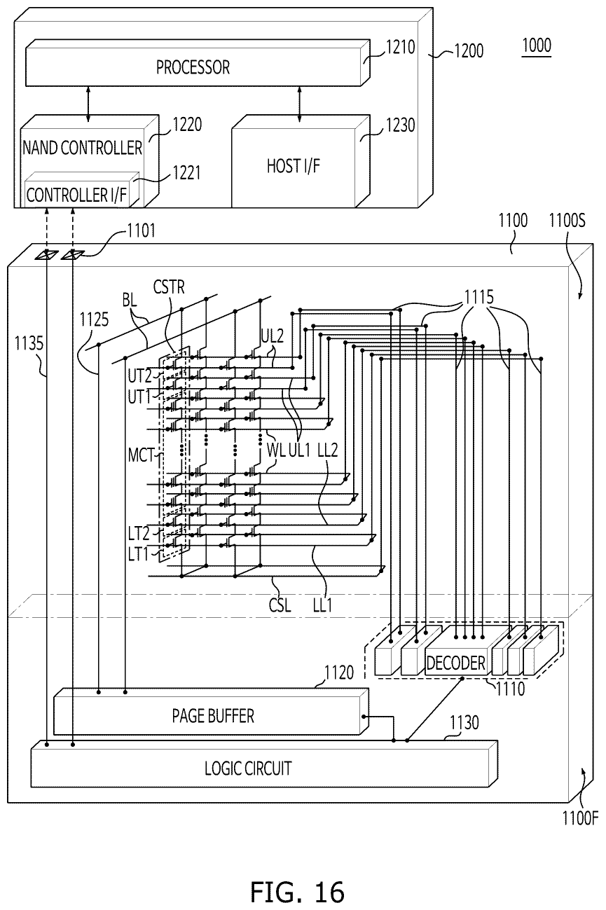

The source structure 102 and 104 may be formed on the cell substrate 100. The source structure 102 and 104 may be disposed between the cell substrate 100 and the mold structure MS. For example, the source structure 102 and 104 may extend along an upper surface of the cell substrate 100. The source structure 102 and 104 may be formed to be connected to a semiconductor pattern of the channel structure CH. For example, a second source layer 104 of the source structure 102 and 104 may be formed through an information storage film and contact the semiconductor pattern. The first source structure 102 and 104 may be provided as a common source line (e.g., CSL in FIG. 16) of the semiconductor device. For example, the source structure 102 and 104 may include polysilicon or metal doped with an impurity, but embodiments are not limited thereto.

In some embodiments, the channel structure CH may be formed through the source structure 102 and 104. For example, a lower portion of the channel structure CH may be formed through the source structure 102 and 104 and disposed in the cell substrate 100.

In some embodiments, the source structure 102 and 104 may include multiple films. For example, the source structure 102 and 104 may include a first source layer 102 and the second source layer 104, which are sequentially stacked on the cell substrate 100. Each of the first source layer 102 and the second source layer 104 may include polysilicon doped with an impurity or polysilicon undoped with an impurity, but embodiments are not limited thereto. The first source layer 102 may be in contact with the semiconductor pattern and may be provided as the common source line (e.g., CSL of FIG. 16) of the semiconductor device. The second source layer 104 may be used as a support layer for preventing the mold stack (e.g., the mold structure MS) from collapsing or falling during a replacement process for forming the first source layer 102.

Although not illustrated, a base insulation film may be interposed between the cell substrate 100 and the first source structure 102 and 104. For example, the base insulation film may include at least one of silicon oxide, silicon nitride, or silicon oxynitride, but is not limited thereto.

The mold structure MS may be disposed on the source structure 102 and 104. The mold structure MS may be disposed on the cell array region CAR and the extension region EXT of the cell substrate 100. The mold structure MS may include a plurality of mold insulation layers 110 and a plurality of gate electrodes 120 which are alternately stacked in a first direction D1. Each of the mold insulation layers 110 and each of the plurality of gate electrodes 120 may have a layered structure that extends parallel to the first surface 100_A of the cell substrate 100. The gate electrodes 120 may be spaced apart from each other by the mold insulation layer 110 and sequentially stacked on the source structure 102 and 104.

The mold insulation layer 110 may include an insulation material. For example, the mold insulation layer 110 may include at least one of silicon oxide, silicon nitride, or silicon oxynitride, but embodiments are not limited thereto.

The gate electrode 120 may include a conductive material. For example, the gate electrode 120 may include a metal such as tungsten (W), cobalt (Co), nickel (Ni), or a semiconductor material such as silicon, but embodiments are not limited thereto.

A cell interlayer insulation film 125 may be formed on the first surface 100_A of the cell substrate 100. The cell interlayer insulation film 125 may be disposed on the mold structure MS to cover the mold structure MS. For example, the cell interlayer insulation film 125 may include at least one of silicon oxide, silicon oxynitride, or a low-k material having a lower dielectric constant than silicon oxide, but embodiments are not limited thereto.

The channel structure CH may be disposed on the cell array region CAR of the cell substrate 100. The channel structure CH may extend in the first direction D1 that intersects a second direction D2 of the first surface 100_A of the cell substrate 100. For example, the first direction D1 may be perpendicular to the second direction D2. The channel structure CH may be formed through the mold structure MS. For example, the channel structure CH may be formed through and intersect with each of the plurality of gate electrodes 120. The channel structure CH may have a pillar shape (e.g., a cylindrical shape) extending in the first direction D1. In some embodiments, a cross-section of the channel structure CH may have an inclined side surface such that its width is progressively narrowed toward the cell substrate 100. However, embodiments are not limited to the above.

In some embodiments, the channel structure CH may include a filling insulation layer, a channel layer, and an information storage film.

The channel layer may extend in the first direction D1 and be formed through the mold structure MS. The channel layer may have various shapes such as a cylindrical shape, a rectangular cylindrical shape, and a filled pillar shape. The channel layer may include, for example, a semiconductor material such as single crystal silicon, polycrystalline silicon, an organic semiconductor material, and/or a carbon nanostructure, but embodiments are not limited thereto.

The information storage film may be interposed between the channel layer and each of the gate electrodes 120. For example, the information storage film may extend along an outer surface of the channel layer. For example, the information storage film may include at least one of silicon oxide, silicon nitride, silicon oxynitride, or a high-k material having a higher dielectric constant than the silicon oxide. For example, the high-k material may include at least one of aluminum oxide, hafnium oxide, lanthanum oxide, tantalum oxide, titanium oxide, lanthanum hafnium oxide, lanthanum aluminum oxide, dysprosium scandium oxide, or a combination thereof.

In some embodiments, the channel structures CH may be arranged in a zigzag pattern. For example, as illustrated in FIG. 1, the channel structures CH may be arranged to alternate with each other in a second direction D2 and a third direction D3. The channel structures CH disposed in the zigzag pattern may further improve the integration density of the semiconductor memory device. In some embodiments, the channel structures CH may be arranged in a honeycomb pattern.

In some embodiments, the information storage film may include multiple films. The information storage film may include a tunnel insulation film, a charge storage film, and a blocking insulation film, which may be sequentially stacked on the outer surface of the channel layer.

The tunnel insulation film may include, for example, silicon oxide or a high-k material (e.g., aluminum oxide (Al₂O₃) or hafnium oxide (HfO₂) having a higher dielectric constant than silicon oxide. For example, the charge storage film may include silicon nitride. The blocking insulation film may include, for example, silicon oxide or a high-k material (e.g., aluminum oxide (Al₂O₃) or hafnium oxide (HfO₂) having a higher dielectric constant than silicon oxide.

In some embodiments, the channel structure CH may further include a filling insulation layer. The filling insulation layer may be formed to fill the interior of the cup-shaped channel layer. For example, the filling insulation layer may include an insulation material such as silicon oxide, but embodiments are not limited thereto.

In some embodiments, a channel pad 132 may be disposed on the channel structure CH. The channel pad 132 may be formed to be connected to the channel layer. For example, the channel pad 132 may be provided in the cell interlayer insulation film 125 and connected to one end of the channel layer. For example, the channel pad 132 may include polysilicon doped with an impurity, but embodiments are not limited thereto.

The mold structure MS may be divided by word line cutting regions WCF to form a memory cell block (e.g., BLK of FIG. 1). For example, the word line cutting region WCF may include at least one of insulation material, silicon oxide, silicon nitride, or silicon oxynitride, but embodiments are not limited thereto.

The bit lines BL may be formed on the mold structure MS. The bit lines BL may intersect with the word line cutting regions WCF. For example, each of the bit lines BL may extend in the third direction D3. The bit lines BL may be disposed along the second direction D2 while being spaced apart from each other.

The bit lines BL may be connected to the channel structures CH that are arranged along the second direction D2. A bit line contact 136 may be formed in the cell interlayer insulation film 125. The bit line BL may be electrically connected to the channel structure CH through the bit line contact 136 and the channel pad 132.

The word line contact 160 may be disposed on the extension region EXT of the cell substrate 100. The word line contact 160 may extend in the first direction D1 and be connected to the gate electrode 120. For example, the word line contact 160 may be formed through a portion of the mold structure MS and connected to the corresponding gate electrode 120. Although FIG. 2 illustrates a configuration in which the word line contact 160 is formed through at least one gate electrode 120 of the plurality of gate electrodes 120 and connected to the corresponding gate electrode 120, embodiments are not limited thereto. In another example, the word line contact 160 may be disposed on the extension region EXT of the cell substrate 100 and connected to the corresponding gate electrode 120 of a plurality of gate electrodes 120 of a stepped structure.

The contact spacer 170 may be disposed on a side surface of the word line contact 160. The contact spacer 170 may extend along the side surface of the word line contact 160 in the first direction D1. The contact spacer 170 may surround the word line contact 160. The contact spacer 170 may include an insulation material. For example, the contact spacer 170 may include a silicon oxide-based insulation material.

A word line via may be disposed on the word line contact 160. The word line via may be disposed in the cell interlayer insulation film 125. The word line contact 160 may be electrically connected to the cell wiring structure 180 through the word line via.

The dummy channel structure 150 may be disposed on the extension region EXT of the cell substrate 100. The dummy channel structure 150 may be disposed around the word line contact 160. The dummy channel structure 150 may include an insulation material. For example, the dummy channel structure 150 may include a silicon oxide-based insulation material. However, embodiments are not limited to the above. As used herein, the term “dummy” is used to refer to a component that has the same or similar structure and shape as other components but does not have a substantial function and exists only as a pattern in the device.

The cell wiring structure 180 may be formed on the mold structure MS. For example, a cell wiring insulation film 182 may be formed on the cell interlayer insulation film 125, and the cell wiring structure 180 may be formed in the cell wiring insulation film 182. The cell wiring structure 180 may be electrically connected to the bit line BL and the word line contact 160. Accordingly, the cell wiring structure 180 may be electrically connected to the channel structure CH and the gate electrode 120. The number and arrangement of layers of the cell wiring structure 180 illustrated herein are merely illustrative, and embodiments are not limited thereto.

In some embodiments, the cell structure CELL may be stacked with the peripheral circuit structure PERI. The peripheral circuit structure PERI may be disposed at a higher level in the first direction than the cell structure CELL. For example, the peripheral circuit structure PERI may be stacked on an upper surface of the cell structure CELL. In some embodiments, the cell structure CELL may be stacked on an upper surface of the peripheral circuit structure PERI.

The peripheral circuit structure PERI may include a peripheral circuit substrate 200, a plurality of peripheral circuit elements 260 disposed on the peripheral circuit substrate 200, an interlayer insulation film 240 stacked on the peripheral circuit substrate 200, and a peripheral wiring structure 280 disposed in the interlayer insulation film 240. The peripheral wiring structure 280 may include a plurality of wiring layers and connection vias disposed in the interlayer insulation film 240.

The peripheral circuit substrate 200 may include a semiconductor substrate. For example, the peripheral circuit substrate 200 may be a single crystal silicon (Si (100)) substrate, but embodiments are not limited thereto. In some embodiments, the peripheral circuit substrate 200 may include a semiconductor substrate such as a silicon substrate, a germanium substrate, or a silicon-germanium substrate.

The peripheral circuit substrate 200 may have a first surface 201 and a second surface 202. The first surface 201 and the second surface 202 may be surfaces opposite to each other. The second surface 202 may be a surface that faces the first surface 201. A peripheral circuit element 260 may be disposed on the first surface 201. A surface on which the peripheral circuit element 260 is disposed may be referred to as a front side of the peripheral circuit substrate 200. For example, the first surface 201 of the peripheral circuit substrate 200 may be referred to as a front side, and the second surface 202 of the peripheral circuit substrate 200 may be referred to as a back side.

The first surface 201 of the peripheral circuit substrate 200 may be disposed to face the cell structure CELL. The front side of the peripheral circuit substrate 200 may be disposed to face the cell structure CELL.

The peripheral circuit substrate 200 may include a first region R1 and a second region R2. The first surface 201 of the peripheral circuit substrate 200 may include a first surface 201 _R1 of the first region R1 and a first surface 201_R2 of the second region R2, and the second surface 202 of the peripheral circuit substrate 200 may include a second surface 202_R1 of the first region R1 and a second surface 202_R2 of the second region R2.

The first region R1 may be a region where a first voltage is applied. The second region R2 may be a region where a second voltage, which is a voltage higher than the first voltage, is applied. The first region R1 and the second region R2 may overlap with each other in the second direction D2. The first region R1 and the second region R2 may be adjacent to each other in the second direction D2.

A thickness of the second region R2 of the peripheral circuit substrate 200 may be greater than a thickness of the first region R1 of the peripheral circuit substrate 200 with respect to the first direction D1. The first surface 201_R1 of the first region R1 and the first surface 201_R2 of the second region R2 may be coplanar with each other. The second surface 202_R2 of the second region R2 may be positioned at a higher level in the first direction than the second surface 202_R1 of the first region R1.

The peripheral circuit element 260 may be disposed on the first surface 201 of the peripheral circuit substrate 200. Each of the plurality of peripheral circuit elements 260 may form a peripheral circuit for controlling an operation of the semiconductor memory device. For example, each of the plurality of peripheral circuit elements 260 may include a logic circuit 1130, a page buffer 1120, a decoder 1110, etc. of FIG. 16.

Each of the plurality of peripheral circuit elements 260 may include a transistor, for example, but is not limited thereto. For example, the peripheral circuit element 260 may include not only various active elements such as transistors, but also various passive elements such as capacitors, registers, and/or inductors.

The plurality of peripheral circuit elements 260 may include a first peripheral circuit element 261 disposed on the first region R1 and a second peripheral circuit element 262 disposed on the second region R2. The first peripheral circuit element 261 may be disposed on the first surface 201_R1 of the first region R1 of the peripheral circuit substrate 200, and the second peripheral circuit element 262 may be disposed on the first surface 201_R2 of the second region R2 of the peripheral circuit substrate 200.

The first voltage may be applied to the first peripheral circuit element 261, and the second voltage may be applied to the second peripheral circuit element 262. For example, the voltage applied to the second peripheral circuit element 262 may be greater than the voltage applied to the first peripheral circuit element 261.

A first element isolation film 211, defining an active region of the first peripheral circuit element 261, may be disposed on one side of the first peripheral circuit element 261. In addition, a second element isolation film 212, defining an active region of the second peripheral circuit element 262, may be disposed on one side of the second peripheral circuit element 262.

The first element isolation film 211 may be formed through the first region R1 of the peripheral circuit substrate 200 in the first direction D1. The first element isolation film 211 may be formed through both the first surface 201_R1 of the first region R1 and the second surface 202_R1 of the first region R1. For example, the first element isolation film 211 may divide adjacent first peripheral circuit elements 261 from a plurality of first peripheral circuit elements 261.

The second element isolation film 212 may be formed through the second region R2 of the peripheral circuit substrate 200 in the first direction D1. The second element isolation film 212 may be defined as a region that overlaps with the second region R2 of the peripheral circuit substrate 200 in the second direction D2. The second element isolation film 212 may be formed through both the first surface 201_R2 of the second region R2 and the second surface 202_R2 of the second region R2. For example, the second element isolation film 212 may divide adjacent second peripheral circuit elements 262 from a plurality of second peripheral circuit elements 262.

A lower surface of the first element isolation film 211 may be positioned at the same level in the first direction as the first surface 201_R1 of the first region R1. An upper surface of the first element isolation film 211 may be positioned at the same level in the first direction as the second surface 202_R1 of the first region R1. A lower surface of the second element isolation film 212 may be positioned at the same level in the first direction as the first surface 201_R2 of the second region R2, and an upper surface of the second element isolation film 212 may be positioned at the same level in the first direction as the second surface 202_R1 of the second region R2.

A length of the second element isolation film 212 in the first direction D1 may be longer than a length of the first element isolation film 211 in the first direction D1. In some embodiments, a width of the second element isolation film 212 in the second direction D2 may be greater than a width of the first element isolation film 211 in the second direction D2.

The width of the first element isolation film 211 may decrease in the second direction D2 along the first direction D1 toward the second surface 202_R1 of the first region R1. The first element isolation film 211 may have a profile that emerges as the first surface 201_R1 of the first region R1 is etched. The width of the second element isolation film 212 in the second direction D2 may decrease along the first direction D1 toward the second surface 202_R2 of the second region R2. The second element isolation film 212 may have a profile that emerges as the first surface 201_R2 of the second region R2 is etched.

Each of the first element isolation film 211 and the second element isolation film 212 may include, for example, an oxide film, a nitride film, or a combination thereof.

A peripheral insulation layer 250 may be disposed on the second surface 202 of the peripheral circuit substrate 200. The peripheral insulation layer 250 may include a first peripheral insulation layer 251 disposed on the first region R1 of the peripheral circuit substrate 200 and a second peripheral insulation layer 252 disposed on the second region R2 of the peripheral circuit substrate 200. The first peripheral insulation layer 251 may be in contact with the first element isolation film 211, and the second peripheral insulation layer 252 may be in contact with the second element isolation film 212. A thickness of the first peripheral insulation layer 251 in the first direction D1 may be greater than a thickness of the second peripheral insulation layer 252 in the first direction D1.

Each of the first peripheral insulation layer 251 and the second peripheral insulation layer 252 may include, for example, an oxide film, a nitride film, or a combination thereof. In some embodiments, the second peripheral insulation layer 252 may not be distinguished from the second element isolation film 212. The second element isolation film 212 may be a portion of the peripheral circuit substrate 200 that is at a level in the first direction corresponding to the second region R2. In addition, the second peripheral insulation layer 252 may be a portion that is at a higher level in the first direction than the second element isolation film 212.

A plurality of body contacts 270 may be disposed on the second surface 202 of the peripheral circuit substrate 200. The plurality of body contacts 270 may include a first body contact 271 disposed on the first region R1 of the peripheral circuit substrate 200 and a second body contact 272 disposed on the second region R2 of the peripheral circuit substrate 200. The body contact 270 may apply an electrical signal, for example, a body voltage to the active region of the peripheral circuit element 260 to adjust a threshold voltage. Specifically, the first body contact 271 may apply the body voltage to the active region of the first peripheral circuit element 261, and the second body contact 272 may apply the body voltage to the active region of the second peripheral circuit element 262.

The first body contact 271 may be in contact with the second surface 202_R1 of the first region R1, and the second body contact 272 may be in contact with the second surface 202_R2 of the second region R2. A length of the first body contact 271 in the first direction D1 may be greater than a length of the second body contact 272 in the first direction D1. For example, an upper surface of the first body contact 271 and an upper surface of the second body contact 272 may be positioned at the same level in the first direction, and a lower surface of the first body contact 271 may be positioned at a lower level in the first direction than a lower surface of the second body contact 272.

A peripheral wiring structure 280 electrically connected to another peripheral wiring structure 280 may be provided on the plurality of peripheral circuit elements 260. The peripheral wiring structure 280 may be formed on the peripheral circuit element 260, and, for example, may be disposed in the interlayer insulation film 240 formed on the front side of the peripheral circuit substrate 200. The peripheral wiring structure 280 may be electrically connected to the peripheral circuit element 260. The number and arrangement of layers of the peripheral wiring structure 280 illustrated in FIG. 2 are merely illustrative, and embodiments are not limited thereto.

In some embodiments, the peripheral circuit structure PERI and the cell structure CELL may be connected to each other by the bonding method. The peripheral circuit structure PERI and the cell structure CELL may be connected to each other through the cell bonding pad 185 formed in the cell structure CELL and a peripheral bonding pad 285 formed in the peripheral circuit structure PERI. In some embodiments, the cell bonding pad 185 and the peripheral bonding pad 285 may include or be copper (Cu), but embodiments are not limited thereto, and that the cell bonding pad 185 and the peripheral bonding pad 285 may include or be various other metals such as aluminum (Al) or tungsten (W). As the cell bonding pad 185 and the peripheral bonding pad 285 are contacting or bonded to each other, the cell wiring structure 180 may be electrically connected to the peripheral wiring structure 280. Accordingly, the bit line BL and/or each of the gate electrodes 120 may be electrically connected to the peripheral circuit element 260.

Referring to FIG. 3, the first peripheral circuit element 261 may include a first gate electrode 261a and a first gate insulation film 261b. The second peripheral circuit element 262 may include a second gate electrode 262a and a second gate insulation film 262b. Because the second voltage applied to the second peripheral circuit element 262 is greater than the first voltage applied to the first peripheral circuit element 261, a width of the second gate electrode 262a may be greater than a width of the first gate electrode 261a. A length of the second gate electrode 262a and the second gate insulation film 262b may be longer than a length of the first gate electrode 261a and the first gate insulation film 261b, respectively, in the second direction D2.

The first element isolation film 211 may include a first base surface 211a coplanar with the first surface 201_R1 of the first region R1. The second element isolation film 212 may include a second base surface 212a coplanar with the first surface 201_R2 of the second region R2. A width of the second base surface 212a may be greater than a width of the first base surface 211a with respect to the second direction D2.

In embodiments, the first peripheral insulation layer 251 may include two opposing side surfaces. Both of the side surfaces of the first peripheral insulation layer 251 may include a respective section inclined so as to diverge away from each other toward the first direction D1. A width of the first peripheral insulation layer 251 in the second direction D2 may include a section that increases as a distance from the second surface 202_R1 of the first region R1 increases along the first direction D1. For example, an angle α between the second surface 202_R1 of the first region R1 and a side surface of the first peripheral insulation layer 251 may be an obtuse angle.

Hereinafter, further embodiments from the embodiments described above will be described. Elements that are same as those already described above may be given the same reference numerals, and detailed description thereof may be omitted.

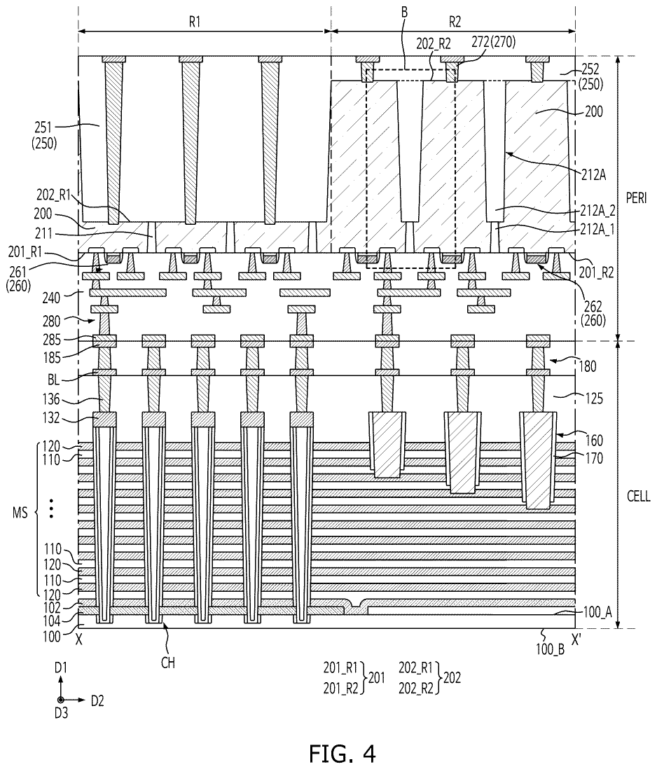

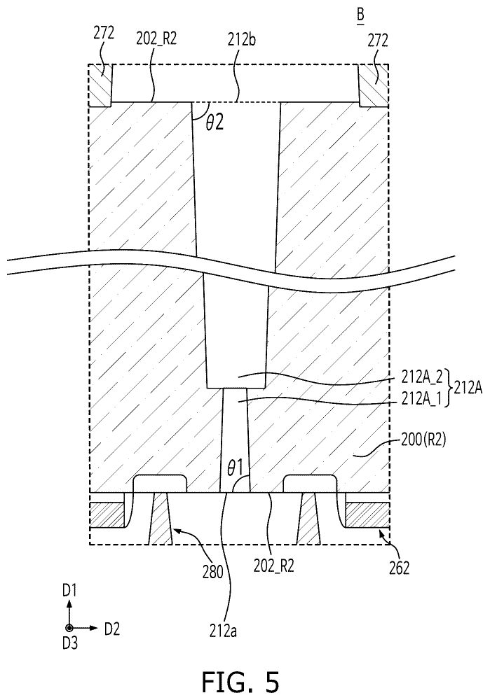

FIG. 4 is a diagram provided to explain a semiconductor memory device according to some embodiments. FIG. 5 is an enlarged view of a boxed area B of FIG. 4. For reference, FIG. 4 may correspond to a cross-sectional view taken along line X-X′ of FIG. 1.

Referring to FIG. 4, the semiconductor memory device according to some embodiments may include the cell structure CELL and the peripheral circuit structure PERI. The peripheral circuit structure PERI may be disposed on the cell structure CELL. Description of the cell structure CELL may be the same as that described above with reference to FIGS. 1 to 3.

The plurality of peripheral circuit elements 260 may include the first peripheral circuit element 261 disposed on the first region R1 and the second peripheral circuit element 262 disposed on the second region R2. The first peripheral circuit element 261 may be disposed on the first surface 201_R1 of the first region R1 of the peripheral circuit substrate 200, and the second peripheral circuit element 262 may be disposed on the first surface 201_R2 of the second region R2 of the peripheral circuit substrate 200.

The peripheral circuit structure PERI may include the first element isolation film 211 that divides adjacent first peripheral circuit elements 261, and the second element isolation film 212A that divides adjacent second peripheral circuit elements 262.

The width of the first element isolation film 211 may decrease in the second direction D2 along the first direction D1 toward the second surface 202_R1 of the first region R1. The first element isolation film 211 may have a profile that emerges as the first surface 201_R1 of the first region R1 is etched.

A length of the second element isolation film 212A in the first direction D1 may be longer than the length of the first element isolation film 211 in the first direction D1. In some embodiments, a width of the second element isolation film 212A in the second direction D2 may be greater than the width of the first element isolation film 211 in the second direction D2.

The second element isolation film 212A may include a first portion 212A_1 and a second portion 212A_2.

The first portion 212A_1 may overlap with the first element isolation film 211 in the second direction D2. A width of the first portion 212A_1 may decrease in the second direction D2 as a distance from the first surface 201_R2 of the second region R2 increases along the first direction D1. A length of the first portion 212A_1 in the first direction D1 may be the same as the length of the first element isolation film 211 in the first direction D1. The first portion 212A_1 may have a profile that emerges as the first surface 201_R2 of the second region R2 is etched.

The second portion 212A_2 may be in contact with the first portion 212A_1. The second portion 212A_2 may be aligned with the first portion 212A_1 in the first direction D1. A width of the second portion 212A_2 may increase in the second direction D2 along the first direction D1 toward the second surface 202_R2 of the second region R2. The width of the second portion 212A_2 in the second direction D2 may be greater than the width of the first portion 212A_1 in the second direction D2. In some embodiments, surfaces on which the second portion 212A_2 and the first portion 212A_1 contact may have the same width in the second direction D2. The second portion 212A_2 may have a profile that emerges as the second surface 202_R2 of the second region R2 is etched.

Referring to FIG. 5, the first portion 212A_1 and the second portion 212A_2 may have the same etching profile. For example, each of the first portion 212A_1 and the second portion 212A_2 may be formed by dry etching.

The first portion 212A_1 of the second element isolation film 212A may include the second base surface 212a coplanar with the first surface 201_R2 of the second region R2. The second portion 212A_2 of the second element isolation film 212A may include a third base surface 212b coplanar with the second surface 202_R2 of the second region R2.

The first portion 212A_1 of the second element isolation film 212A may have an angle θ1 between the side surface of the first portion 212A_1 and the second base surface 212a. The second portion 212A_2 of the second element isolation film 212A may have an angle θ2 between the side surface of the second portion 212A_2 and the third base surface 212b.

The angle θ1 between the side surface of the first portion 212A_1 and the second base surface 212a may be the same as the angle θ2 between the side surface of the second portion 212A_2 and the third base surface 212b. Because the first portion 212A_1 and the second portion 212A_2 are each formed by the dry etching process, the side surface of the first portion 212A_1 and the side surface of the second portion 212A_2 may each have the same inclination.

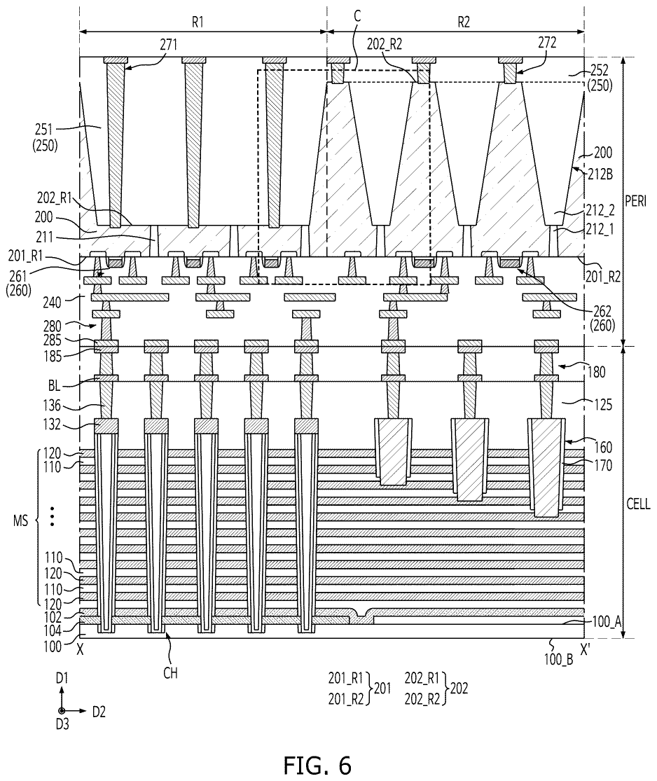

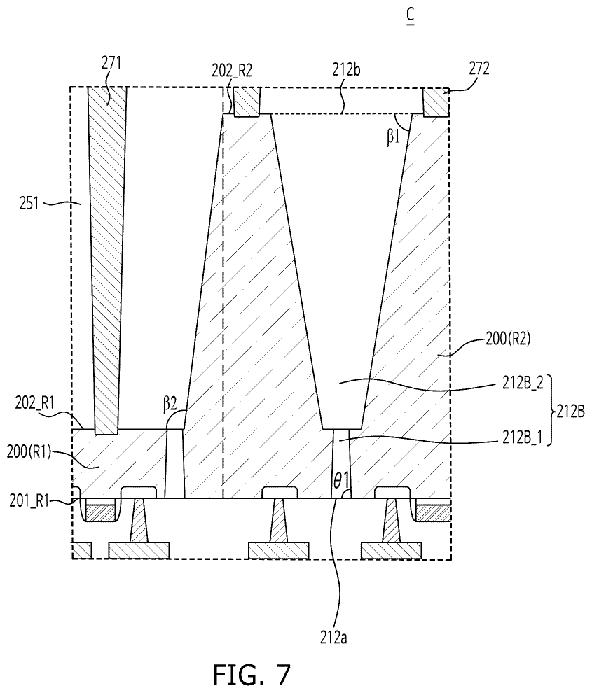

FIG. 6 is a diagram provided to explain a semiconductor memory device according to some embodiments. FIG. 7 is an enlarged view of a boxed area C of FIG. 6. For reference, FIG. 6 may correspond to a cross-sectional view taken along line X-X′ of FIG. 1.

Referring to FIG. 6, the semiconductor memory device according to some embodiments may include the cell structure CELL and the peripheral circuit structure PERI. The peripheral circuit structure PERI may be disposed on the cell structure CELL. Description of the cell structure CELL may be the same as that described above with reference to FIGS. 1 to 3.

The plurality of peripheral circuit elements 260 may include the first peripheral circuit element 261 disposed on the first region R1 and the second peripheral circuit element 262 disposed on the second region R2. The first peripheral circuit element 261 may be disposed on the first surface 201_R1 of the first region R1 of the peripheral circuit substrate 200, and the second peripheral circuit element 262 may be disposed on the first surface 201_R2 of the second region R2 of the peripheral circuit substrate 200.

The peripheral circuit structure PERI may include the first element isolation film 211 that divides adjacent first peripheral circuit elements 261 from each other, and a second element isolation film 212B that divides adjacent second peripheral circuit elements 262 from each other.

The width of the first element isolation film 211 may decrease in the second direction D2 along the first direction D1 toward the second surface 202_R1 of the first region R1. The first element isolation film 211 may have a profile that emerges as the first surface 201_R1 of the first region R1 is etched.

A length of the second element isolation film 212B in the first direction D1 may be longer than the length of the first element isolation film 211 in the first direction D1. In some embodiments, a width of the second element isolation film 212B in the second direction D2 may be greater than the width of the first element isolation film 211 in the second direction D2.

The second element isolation film 212A may include a first portion 212B_1 and a second portion 212B_2.

The first portion 212B_1 may overlap with the first element isolation film 211 in the second direction D2. A width of the first portion 212B_1 may decrease in the second direction D2 as a distance from the first surface 201_R2 of the second region R2 increases along the first direction D1. A length of the first portion 212B_1 in the first direction D1 may be the same as the length of the first element isolation film 211 in the first direction D1. The first portion 212B_1 may have a profile that emerges as the first surface 201_R2 of the second region R2 is etched.

The second portion 212B_2 may be in contact with the first portion 212B_1. The second portion 212B_2 may be aligned with the first portion 212B_1 in the first direction D1. A width of the second portion 212B_2 may increase in the second direction D2 along the first direction D1 toward the second surface 202_R2 of the second region R2. A rate at which the width of the second portion 212B_2 of the second element isolation film 212B increases in the second direction D2 may be greater than a rate at which the width of the second portion 212A_2 of the second element isolation film 212A shown in FIG. 5 increases in the second direction D2.

The width of the second portion 212B_2 in the second direction D2 may be greater than the width of the first portion 212B_1 in the second direction D2. In some embodiments, surfaces on which the second portion 212B_2 and the first portion 212B_1 contact may have the same width in the second direction D2. The second portion 212B_2 may have a profile that emerges as the second surface 202_R2 of the second region R2 is etched. For example, the second portion 212B_2 may be formed by wet etching.

Referring to FIG. 7, the first portion 212B_1 and the second portion 212B_2 may have different etching profiles. For example, the first portion 212B_1 may be formed by dry etching, and the second portion 212B_2 may be formed by wet etching.

The first portion 212B_1 of the second element isolation film 212B may include the second base surface 212a coplanar with the first surface 201_R2 of the second region R2. The second portion 212B_2 of the second element isolation film 212B may include the third base surface 212b coplanar with the second surface 202_R2 of the second region R2.

The first portion 212B_1 of the second element isolation film 212B may have the angle θ1 between the side surface of the first portion 212B_1 and the second base surface 212a. The second portion 212B_2 of the second element isolation film 212B may have an angle β1 between the side surface of the second portion 212B_2 and the third base surface 212b. The angle β1 between the side surface of the second portion 212B_2 and the third base surface 212b may be less than the angle θ1 between the side surface of the first portion 212B_1 and the second base surface 212a. For example, the angle β1 between the side surface of the second portion 212B_2 and the third base surface 212b may be determined according to the crystal orientation of the peripheral circuit substrate 200. For example, if the peripheral circuit substrate 200 includes or is single crystal silicon with a (100) crystal orientation, the angle β1 between the side surface of the second portion 212B_2 and the third base surface 212b may have an angle of about 54.7 degrees. As described above, because the first portion 212B_1 and the second portion 212B_2 are formed by different etching processes, the side surface of the first portion 212A_1 and the side surface of the second portion 212A_2 may have different inclinations.

The first peripheral insulation layer 251 may have an angle β2 between the side surface of the first peripheral insulation layer 251 and the second surface 202_R1 of the first region R1. Both side surfaces of the first peripheral insulation layer 251 may be inclined so as to diverge away from each other toward the first direction D1. The width of the first peripheral insulation layer 251 in the second direction D2 may increase as a distance from the second surface 202_R1 of the first region R1 increases along the first direction D1. For example, the angle β2 between the second surface 202_R1 of the first region R1 and the side surface of the first peripheral insulation layer 251 may be an obtuse angle. The angle β2 between the second surface 202_R1 of the first region R1 and the side surface of the first peripheral insulation layer 251 may be greater than the angle α between the second surface 202_R1 of the first region R1 and the side surface of the first peripheral insulation layer 251 illustrated in FIG. 3.

The angle β1 between the second surface 202_R1 of the first region R1 and the side surface of the first peripheral insulation layer 251 and the angle β2 between the side surface of the first peripheral insulation layer 251 and the second surface 202_R1 of the first region R1 may be in a complementary angle relationship. For example, the sum of the angle β1 between the second surface 202_R1 of the first region R1 and the side surface of the first peripheral insulation layer 251 and the angle β2 between the side surface of the first peripheral insulation layer 251 and the second surface 202_R1 of the first region R1 may be 180 degrees. For example, the angle β2 between the side surface of the first peripheral insulation layer 251 and the second surface 202_R1 of the first region R1 may also be determined according to the crystal orientation of the peripheral circuit substrate 200.

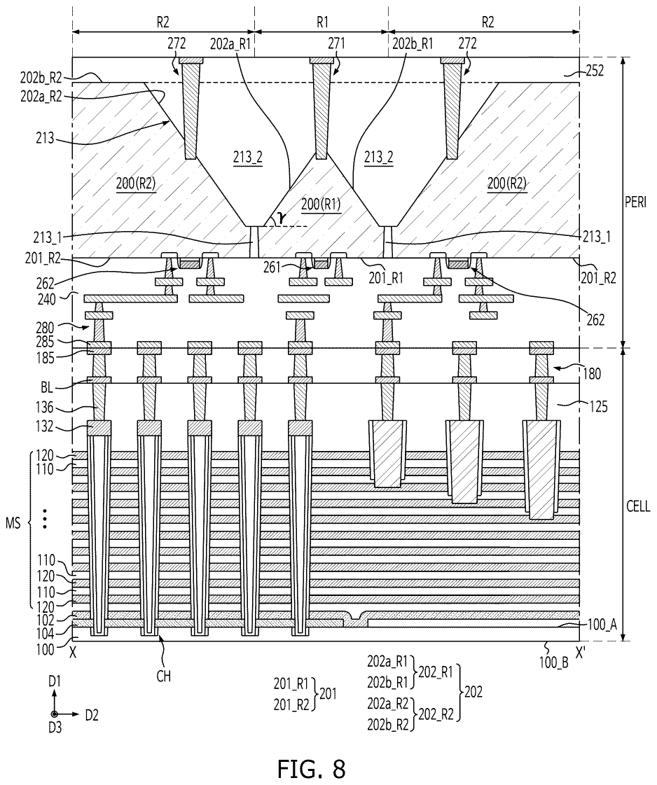

FIG. 8 is a diagram provided to explain a semiconductor memory device according to some embodiments.

Referring to FIG. 8, the semiconductor memory device according to some embodiments may include the cell structure CELL and the peripheral circuit structure PERI. The peripheral circuit structure PERI may be disposed on the cell structure CELL. Description of the cell structure CELL may be the same as that described above with reference to FIGS. 1 to 3.

The plurality of peripheral circuit elements 260 may be disposed on the peripheral circuit substrate 200. Specifically, the plurality of peripheral circuit elements 260 may be disposed on the first surface 201 of the peripheral circuit substrate 200. The peripheral circuit substrate 200 may include or be single crystal silicon. For example, the peripheral circuit substrate 200 may include or be single crystal silicon with the (100) crystal orientation.

The peripheral circuit substrate 200 may include the first region R1 and the second region R2 disposed on both sides of the first region R1. The first region R1 and the second region R2 may be adjacent to each other in the second direction D2. The first region R1 may be disposed between the second regions R2.

The plurality of peripheral circuit elements 260 may include the first peripheral circuit element 261 disposed on the first region R1 and the second peripheral circuit element 262 disposed on the second region R2. The first peripheral circuit element 261 may be disposed on the first surface 201_R1 of the first region R1 of the peripheral circuit substrate 200, and the second peripheral circuit element 262 may be disposed on the first surface 201_R2 of the second region R2 of the peripheral circuit substrate 200.

The peripheral circuit structure PERI may include a third element isolation film 213 that divides a first peripheral circuit element 261 and a second peripheral circuit element 262. For example, the third element isolation film 213 may be positioned on a boundary between the first region R1 and the second region R2.

The third element isolation film 213 may include a first portion 213_1 and a second portion 213_2.

A width of the first portion 213_1 may decrease in the second direction D2 as a distance from the first surface 201 increases along the first direction D1. The first portion 213_1 may have a profile that emerges as the first surface 201 is etched. A width of the second portion 213_2 may decrease in the second direction D2 as a distance from the second surface 202 increases along the first direction D1. The second portion 213_2 may have a profile that emerges as the second surface 202 is etched. For example, the first portion 213_1 may be formed by dry etching, and the second portion 213_2 may be formed by wet etching.

The second portion 213_2 of the third element isolation film 213 may be etched along a crystal orientation by wet etching.

The second surface 202_R1 of the first region R1 of the peripheral circuit substrate 200 may include a first inclined surface 202a_R1 and a second inclined surface 202b_R1. The first inclined surface 202a_R1 and the second inclined surface 202b_R1 may have profiles formed through wet etching. The first region R1 of the peripheral circuit substrate 200 may have an approximately triangular shape. For example, if the peripheral circuit substrate 200 is single crystal silicon with the (100) crystal orientation, an angle γ between the first inclined surface 202a_R1 or the second inclined surface 202b_R1 and the first surface 201_R1 of the first region R1 may be about 53 to about 56 degrees, or 53.5 to 55.5 degrees, or 54 to 55 degrees. Specifically, the angle γ between the first inclined surface 202a_R1 or the second inclined surface 202b_R1 and the first surface 201_R1 of the first region R1 may be about 54.7 degrees. In some embodiments, the first inclined surface 202a_R1 and the second inclined surface 202b_R1 may be symmetrical to each other.

The second surface 202_R2 of the second region R2 of the peripheral circuit substrate 200 may include an inclined surface 202a_R2 and a horizontal surface 202b_R2. The smaller value among the angles between the inclined surface 202a_R2 and the horizontal surface 202b_R2 may be equal to the angle γ between the first inclined surface 202a_R1 or the second inclined surface 202b_R1 and the first surface 201_R1 of the first region R1. In some embodiments, the second surface 202_R2 of the second region R2 of the peripheral circuit substrate 200 may include different inclined surfaces instead of the horizontal surface 202b_R2. Specifically, if the first region R1 is disposed on both sides of the second region R2, the second surface 202_R2 of the second region R2 of the peripheral circuit substrate 200 may include two inclined surfaces.

The thickness of the second region R2 of the peripheral circuit substrate 200 may be greater than the thickness of the first region R1. For example, a thickness from the first surface 201 to the horizontal surface 202b_R2 of the second region R2 may be greater than a thickness from the first surface 201 to the first region R1. The thickness of the first region R1 may be defined as a distance from the first surface 201 to a point where the first inclined surface 202a_R1 and the second inclined surface 202b_R1 meet.

Because the first inclined surface 202a_R1 and the second inclined surface 202b_R1 have profiles formed through wet etching, the second portions 213_2 of adjacent third element isolation film 213 may be connected to each other. If the length of the first region R1 in the first direction D1 is not long enough, the second portions 213_2 of adjacent third element isolation films 213 may be connected to each other. In some embodiments, if the length of the first region R1 in the first direction D1 is sufficiently long, the second portions 213_2 of adjacent third element isolation films 213 may be separated from each other.

The first body contact 271 may be disposed on the second surface 202_R1 of the first region R1, and the second body contact 272 may be disposed on the second surface 202_R2 of the second region R2. The upper surface of the first body contact 271 and the upper surface of the second body contact 272 may be positioned at the same level in the first direction. The lower surface of the first body contact 271 may be in contact with a portion where the first inclined surface 202a_R1 and the second inclined surface 202b_R1 meet. The lower surface of the second body contact 272 may be disposed on the inclined surface 202a_R2 of the second region R2.

The length of the first body contact 271 in the first direction D1 and the length of the second body contact 272 in the first direction D1 may be the same as each other. However, this is only an example, and the shapes of the first body contact 271 and the second body contact 272 are not limited to the above. In some embodiments, the length of the first body contact 271 in the first direction D1 and the length of the second body contact 272 in the first direction D1 may be different from each other.

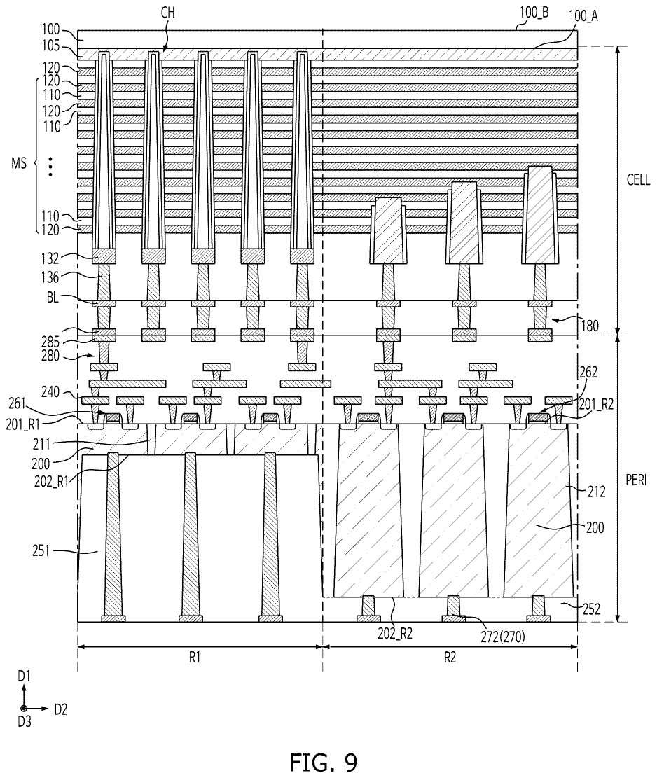

FIG. 9 is a diagram provided to explain a semiconductor memory device according to some embodiments.

Referring to FIG. 9, the semiconductor memory device according to some embodiments may include the cell structure CELL and the peripheral circuit structure PERI. The cell structure CELL may be stacked on the peripheral circuit structure PERI. Specifically, the peripheral circuit structure PERI may be disposed at a higher level in the first direction than the cell structure CELL. The peripheral circuit structure PERI may be disposed on the upper surface of the cell structure CELL.

The cell structure CELL may include the cell substrate 100, a common source plate 105, the mold structure MS, the channel structure CH, the bit line BL, the word line contact 160, the contact spacer 170, the cell wiring structure 180, etc.

The common source plate 105 may be disposed on the first surface 100_A of the cell substrate 100. The common source plate 105 may be disposed on the cell array region CAR, the extension region EXT, and the through region THR illustrated in FIG. 1. The common source plate 105 may be connected to the channel structure CH. For example, the common source plate 105 may be electrically connected to the channel layer of the channel structure CH. The common source plate 105 may be connected to the source contact 184 in the through region THR. The common source plate 105 may be provided as a common source line (e.g., CSL of FIG. 16) of the semiconductor memory device. For example, the common source plate 105 may include polycrystalline silicon or metal doped with an impurity, but embodiments are not limited thereto.

The mold structure MS may be disposed on the common source plate 105. The mold structure MS may be disposed on the cell array region CAR and the extension region EXT of the cell substrate 100. The mold structure MS may include the plurality of mold insulation layers 110 and the plurality of gate electrodes 120 which are alternately stacked in the first direction D1. Each of the mold insulation layers 110 and each of the gate electrodes 120 may have a layered structure with each other that extends parallel to the first surface 100_A of the cell substrate 100. The gate electrodes 120 may be sequentially stacked on the common source plate 105 and spaced apart from each other by the mold insulation layers 110.

In some embodiments, some gate electrodes 120 of the plurality of gate electrodes 120 may be provided as a ground selection line GSL of the semiconductor memory device. The other gate electrodes 120 of the plurality of gate electrodes 120 may be provided as a string selection line SSL of the semiconductor memory device. For example, among the plurality of gate electrodes 120, the gate electrode 120 adjacent to the common source plate 105 may be provided as the ground selection line GSL. Among the plurality of gate electrodes 120, the gate electrode 120 adjacent to the bit line BL may be provided as the string selection line SSL. However, embodiments are not limited to the above. The arrangement and number of the ground selection lines GSL and the string selection lines SSL may vary.

Description of the peripheral circuit structure PERI may be the same as the above description with reference to FIGS. 1 to 8. For example, the peripheral circuit structure PERI of FIG. 9 is merely an example, and the peripheral circuit structures PERI according to various embodiments described above may be applicable.

The cell structure CELL may be bonded onto the peripheral circuit structure PERI. A structure may be provided by forming the first chip including the peripheral circuit structure PETI on the first wafer and the second chip including the cell structure CELL on the second wafer, and then connecting the first and second chips to each other through a bonding method.

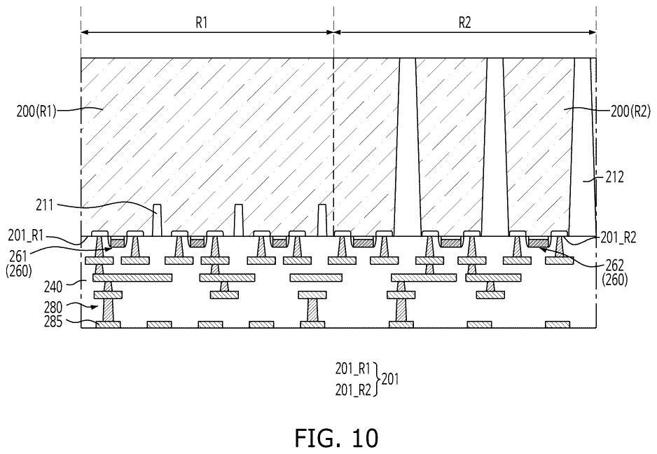

FIGS. 10 to 12 are diagrams provided to explain a method for manufacturing a semiconductor memory device according to some embodiments.

The wafer or the chip on which the peripheral circuit structure is to be formed may have been previously bonded onto the wafer or the chip where the cell structure CELL is formed. For example, the bonding method may be a hybrid bonding.

Referring to FIG. 10, the first element isolation film 211, the second element isolation film 212, and the plurality of peripheral circuit elements 260 may be formed on the first surface 201 or the front side of the peripheral circuit substrate 200.

Etching may proceed from the first surface 201 of the peripheral circuit substrate 200. For example, the etching process may be performed by dry etching. A portion of the peripheral circuit substrate 200 may be selectively removed from the first surface 201 by the dry etching process to form a trench.

In the first region R1, a trench may be formed from the first surface 201 to a predetermined position in the peripheral circuit substrate 200. In the second region R2, a trench may be formed from the first surface 201 to the back side of the peripheral circuit substrate 200. For example, a depth of the trench formed in the second region R2 may be deeper than a depth of the trench formed in the first region R1.

Silicon oxide, silicon nitride, or a combination thereof may fill the interior of the trench. The first element isolation film 211 and the second element isolation film 212 may be formed within the trench. The first element isolation film 211 may be formed through a portion of the first region R1 and may extend completely through the second element isolation film 212.

A first peripheral circuit element 261 may be formed between adjacent first element isolation films 211. A second peripheral circuit element 262 may be formed on the peripheral circuit substrate 200 between adjacent second element isolation films 212. For example, the first gate insulation film 261b and the first gate electrode 261a may be formed on the peripheral circuit substrate 200 separated by the first element isolation film 211, and the second gate insulation film 262b and the second gate electrode 262a may be formed on the peripheral circuit substrate 200 separated by the second element isolation film 212. The interlayer insulation film 240, the peripheral wiring structure 280, the peripheral bonding pad 285, etc. may be formed.

A planarization process may be performed on the back side of the peripheral circuit substrate 200. For example, the planarization process may be performed by a Chemical Physical Polishing (CMP) process. The planarization may proceed to a position where the second element isolation film 212 may be exposed. The second surface 202_R2 of the second region R2 may be formed by the planarization process.

The first region R1 and the second region R2 of the peripheral circuit substrate 200 may have the same thickness. The second peripheral circuit element 262 may be completely separated from each other by the second element isolation film 212. For example, the second element isolation film 212 may be exposed by the planarization process, and the first element isolation film 211 may not be exposed.

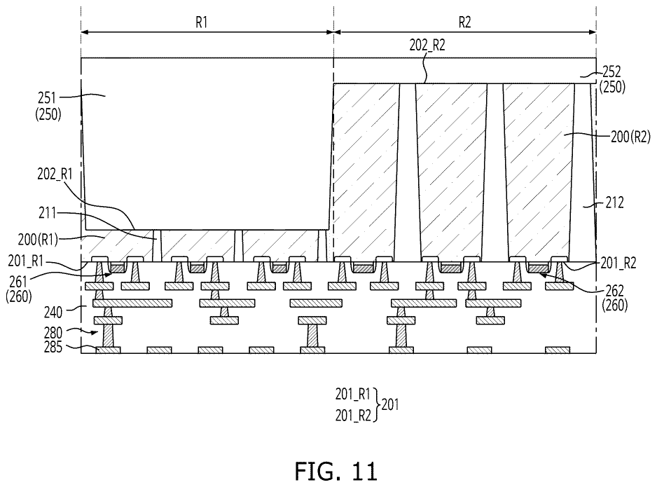

Referring to FIG. 11, an etch back process may be selectively performed on the back side of the peripheral circuit substrate 200. An etching mask may be disposed on the second region R2 of the peripheral circuit substrate 200, and the etch back process may be performed on the first region R1. The etch back may proceed to a position where the first element isolation film 211 may be exposed. The second surface 202_R1 of the first region R1 may be formed by the etch back process.

In some embodiments, an inclined surface forming a predetermined angle with the second surface 202_R1 may be formed in the first region R1 of the peripheral circuit substrate 200. This may be an etching profile formed by the etch back process.

The first region R1 and the second region R2 of the peripheral circuit substrate 200 may have different thicknesses. Specifically, the thickness of the second region R2 of the peripheral circuit substrate 200 may be greater than the thickness of the first region R1 of the peripheral circuit substrate 200.

The peripheral insulation layer 250 may be formed on the second surface of the peripheral circuit substrate 200. The peripheral insulation layer 250 may be formed in both the first region R1 and the second region R2. The peripheral insulation layer 250 may include the first peripheral insulation layer 251 disposed on the second surface 202_R1 of the first region R1, and the second peripheral insulation layer 252 disposed on the second surface 202_R2 of the second region R2 and the second portion 212A_2 of the second element isolation film.

Silicon oxide with a sufficient thickness may be formed on an upper surface of the first peripheral insulation layer 251 so as to be positioned at the same level as, or higher level in the first direction than an upper surface of the second peripheral insulation layer 252. A planarization process may be performed on the upper surface of the first peripheral insulation layer 251 and the upper surface of the second peripheral insulation layer 252. The upper surface of the first peripheral insulation layer 251 and the upper surface of the second peripheral insulation layer 252 may be positioned at the same level. For example, the upper surface of the first peripheral insulation layer 251 and the upper surface of the second peripheral insulation layer 252 may be coplanar with each other.

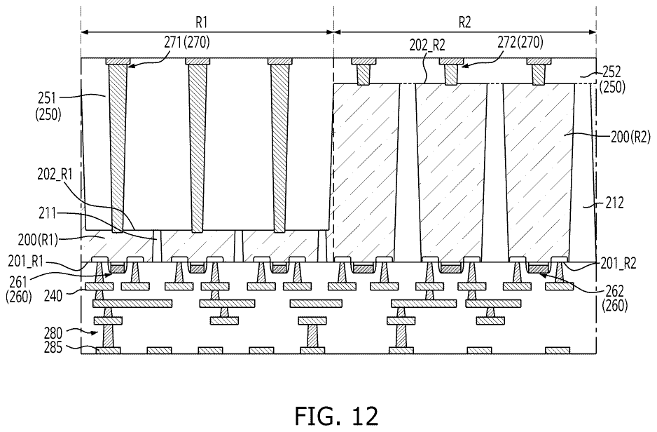

Referring to FIG. 12, each of the first peripheral insulation layer 251 and the second peripheral insulation layer 252 may be selectively etched and filled with a conductive material. The first peripheral insulation layer 251 may be removed to a position where the second surface 202_R1 of the first region R1 may be exposed, and the second peripheral insulation layer 252 may be removed to a position where the second surface 202_R2 of the second region R2 may be exposed.

The body contact 270 may be formed in the portions from which the first peripheral insulation layer 251 and the second peripheral insulation layer 252 have been removed. The portions from which the first peripheral insulation layer 251 and the second peripheral insulation layer 252 have been removed may be filled with a conductive material. The first body contact 271 may be formed within the first peripheral insulation layer 251, and the second body contact 272 may be formed within the second peripheral insulation layer 252.

The lower surface of the first body contact 271 may be in contact with the first region R1 of the peripheral circuit substrate 200, and the lower surface of the second body contact 272 may be in contact with the second region R2 of the peripheral circuit substrate 200. The upper surface of the first body contact 271 and the upper surface of the second body contact 272 may be coplanar with the upper surface of the first peripheral insulation layer 251 and the upper surface of the second peripheral insulation layer 252. The first body contact 271 and the second body contact 272 may be formed with upper wiring through which the body voltage may be applied.

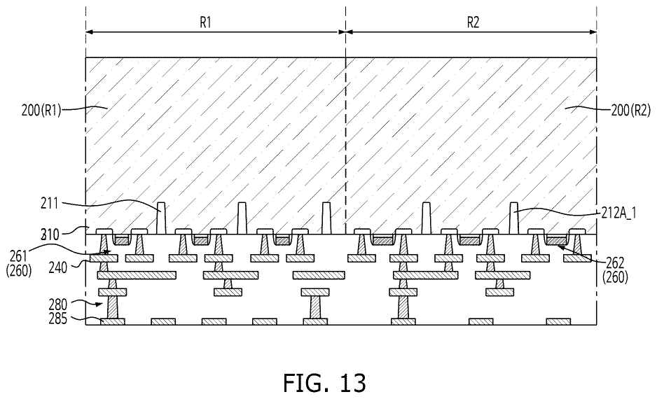

FIGS. 13 to 15 are diagrams provided to explain a method for manufacturing a semiconductor memory device according to some embodiments. Hereinafter, for convenience of description, detailed descriptions of the same operations or components as those of the embodiments of FIGS. 10 to 12 may be omitted.

Referring to FIG. 13, the first element isolation film 211, the first portion 212A_1 of the second element isolation film, and the plurality of peripheral circuit elements 260 may be formed on the first surface 201 or on the front side of the peripheral circuit substrate 200.

Etching may proceed from the first surface 201 of the peripheral circuit substrate 200. For example, the etching process may be performed by dry etching. A portion of the peripheral circuit substrate 200 may be selectively removed from the first surface 201 by the dry etching process to form a trench.

In the first region R1 and the second region R2, a trench may be formed from the first surface 201 to a predetermined position in the peripheral circuit substrate 200. For example, a depth of the trench formed in the first region R1 may be the same as a depth of the trench formed in the second region R2. Silicon oxide, silicon nitride, or a combination thereof may fill the interior of the trench.

The first element isolation film 211 and the first portion 212A_1 of the second element isolation film may be formed within the trench. The first element isolation film 211 and the first portion 212A_1 of the second element isolation film may be formed through a portion of the first region R1. The lengths of the first element isolation film 211 and the first portion 212A_1 of the second element isolation film may be the same as each other.

A first peripheral circuit element 261 may be formed between adjacent first element isolation films 211. A second peripheral circuit element 262 may be formed on the peripheral circuit substrate 200 between the first portions 212A_1 of adjacent second element isolation films. For example, the first gate insulation film 261b and the first gate electrode 261a may be formed on the peripheral circuit substrate 200 between adjacent first element isolation films 211, and the second gate insulation film 262b and the second gate electrode 262a may be formed on the peripheral circuit substrate 200 between the first portions 212A_1 of adjacent second element isolation films. The interlayer insulation film 240, the peripheral wiring structure 280, the peripheral bonding pad 285, etc. may be formed.

A planarization process may be performed on the back side of the peripheral circuit substrate 200 and proceed to a predetermined position. For example, the planarization process may be performed by a Chemical Physical Polishing (CMP) process. The second surface 202_R2 of the second region R2 may be formed by the planarization process. The first region R1 and the second region R2 of the peripheral circuit substrate 200 may have the same thickness.

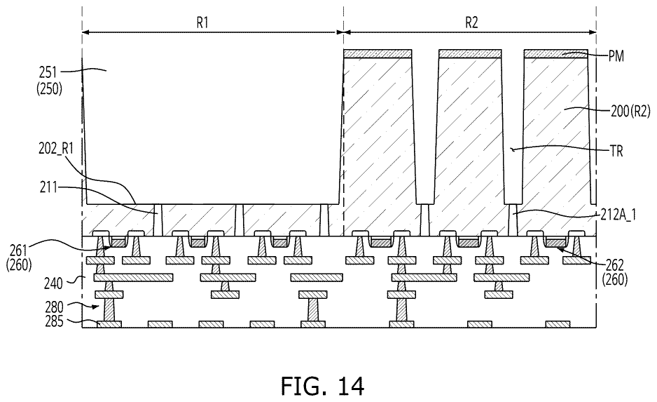

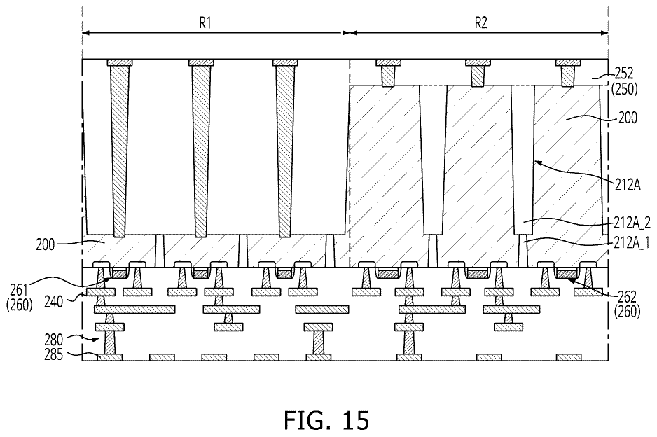

Referring to FIGS. 14 and 15, an etch back process may be selectively performed on the back side of the peripheral circuit substrate 200. The etch back process may be performed on the first region R1. The etch back may proceed to a position where the first element isolation film 211 may be exposed. The second surface 202_R1 of the first region R1 may be formed by the etch back process. A pattern mask PM may be disposed on the second region R2 of the peripheral circuit substrate 200. A portion of the second region R2 exposed by the pattern mask PM may be selectively removed. A trench TR may be formed on the second region R2 by the etching process. Both the etch back process performed on the first region R1 and the etching process performed on the second region R2 may be dry etching. In some embodiments, the etch back process performed on the first region R1 and the etching process performed on the second region R2 may be performed simultaneously.

In some embodiments, an inclined surface forming a predetermined angle with the second surface 202_R1 may be formed in the first region R1 of the peripheral circuit substrate 200. This may be an etching profile formed by the etch back process.

The first region R1 and the second region R2 of the peripheral circuit substrate 200 may have different thicknesses. Specifically, the thickness of the second region R2 of the peripheral circuit substrate 200 may be greater than the thickness of the first region R1 of the peripheral circuit substrate 200.

Silicon oxide, silicon nitride, or a combination thereof may fill the interior of the trench TR formed in the second region R2 of the peripheral circuit substrate 200. Silicon oxide, silicon nitride, or a combination thereof filled in the trench TR may form the second portion 212A_2 of the second element isolation film.

The peripheral insulation layer 250 may be formed on the second surface of the peripheral circuit substrate 200. The peripheral insulation layer 250 may be formed in both the first region R1 and the second region R2. The peripheral insulation layer 250 may include the first peripheral insulation layer 251 disposed on the second surface 202_R1 of the first region R1, and the second peripheral insulation layer 252 disposed on the second surface 202_R2 of the second region R2 and the second portion 212A_2 of the second element isolation film.

The peripheral insulation layer 250 may be formed on the second surface of the peripheral circuit substrate 200. The peripheral insulation layer 250 may be formed in both the first region R1 and the second region R2. The peripheral insulation layer 250 may include the first peripheral insulation layer 251 disposed on the second surface 202_R1 of the first region R1 and the second peripheral insulation layer 252 disposed on the second surface 202_R2 of the second region R2.

Silicon oxide with a sufficient thickness may be formed on an upper surface of the first peripheral insulation layer 251 so as to be positioned at the same level as, or higher level in the first direction than an upper surface of the second peripheral insulation layer 252. A planarization process may be performed on the upper surface of the first peripheral insulation layer 251 and the upper surface of the second peripheral insulation layer 252. The upper surface of the first peripheral insulation layer 251 and the upper surface of the second peripheral insulation layer 252 may be positioned at the same level in the first direction. For example, the upper surface of the first peripheral insulation layer 251 and the upper surface of the second peripheral insulation layer 252 may be coplanar with each other.

Each of the first peripheral insulation layer 251 and the second peripheral insulation layer 252 may be selectively etched and filled with a conductive material. The first peripheral insulation layer 251 may be removed to a position where the second surface 202_R1 of the first region R1 may be exposed, and the second peripheral insulation layer 252 may be removed to a position where the second surface 202_R2 of the second region R2 may be exposed.

The body contact 270 may be formed in the portions from which the first peripheral insulation layer 251 and the second peripheral insulation layer 252 have been removed. The portions from which the first peripheral insulation layer 251 and the second peripheral insulation layer 252 have been removed may be filled with a conductive material. The first body contact 271 may be formed within the first peripheral insulation layer 251, and the second body contact 272 may be formed within the second peripheral insulation layer 252.

The lower surface of the first body contact 271 may be in contact with the first region R1 of the peripheral circuit substrate 200, and the lower surface of the second body contact 272 may be in contact with the second region R2 of the peripheral circuit substrate 200. The upper surface of the first body contact 271 and the upper surface of the second body contact 272 may be coplanar with the upper surface of the first peripheral insulation layer 251 and the upper surface of the second peripheral insulation layer 252. The first body contact 271 and the second body contact 272 may be formed with upper wiring through which the body voltage may be applied.

FIG. 16 is a block diagram provided as an example to explain an electronic system according to some embodiments.

Referring to FIG. 16, an electronic system 1000 may include a semiconductor device 1100 described with reference to FIGS. 1 and 9 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive device (SSD), a universal serial bus (USB), a computing system, a medical device, or a communication device including one or the plurality of semiconductor devices 1100.

The semiconductor device 1100 may be, for example, the NAND flash memory device described above with reference to FIGS. 1 and 9. The semiconductor device 1100 may include a first structure 1100F and a second structure 1100S on the first structure 1100F. The first structure 1100F may be a peripheral circuit structure including a decoder circuit 1110, the page buffer 1120, and the logic circuit 1130. The first structure 1100F may include a peripheral circuit structure (e.g., PERI of FIG. 2). For example, the first structure 1100F may include a plurality of peripheral circuit structures stacked through a bonding method. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may vary according to various embodiments.

In some embodiments, each of the upper transistors UT1 and UT2 may include a string selection transistor, and each of the lower transistors LT1 and LT2 may include a ground selection transistor. Each of the gate lower lines LL1 and LL2 may be gate electrodes of the lower transistors LT1 and LT2. Each of the word lines WL may be gate electrodes of the memory cell transistors MCT, and each of the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be each be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one select memory cell transistor among the plurality of memory cell transistors MCT. The decoder circuit 1110 and the page buffer 1120 may be controlled by the logic circuit 1130. The semiconductor device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller may be a processor (i.e., a hardware circuit), such as a microprocessor, a CPU (Central Processing Unit), a GPU (graphics processor), a digital signal processor (DSP), a field-programmable gate array (FPGA), etc., and may be part of a computer. Such a controller may be formed by several interconnected controllers and may be configured by software.

For example, the controller 1200 may include a processor 1210, a NAND controller 1220, and a host interface 1230. According to some embodiments, the electronic system 1000 may include the plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to predetermined firmware, and may control the NAND controller 1220 to access the semiconductor device 1100. The NAND controller 1220 may include a NAND interface 1221 that processes communication with the semiconductor device 1100. A control command for controlling the semiconductor device 1100, data to be written in the memory cell transistors MCT of the semiconductor device 1100, data to be read from the memory cell transistors MCT of the semiconductor device 1100, etc. may be transmitted through the NAND interface 1221. The host interface 1230 may provide a communication function between the electronic system 1000 and an external host. Upon receiving a control command from the external host through the host interface 1230, the processor 1210 may control the semiconductor device 1100 in response to the control command.

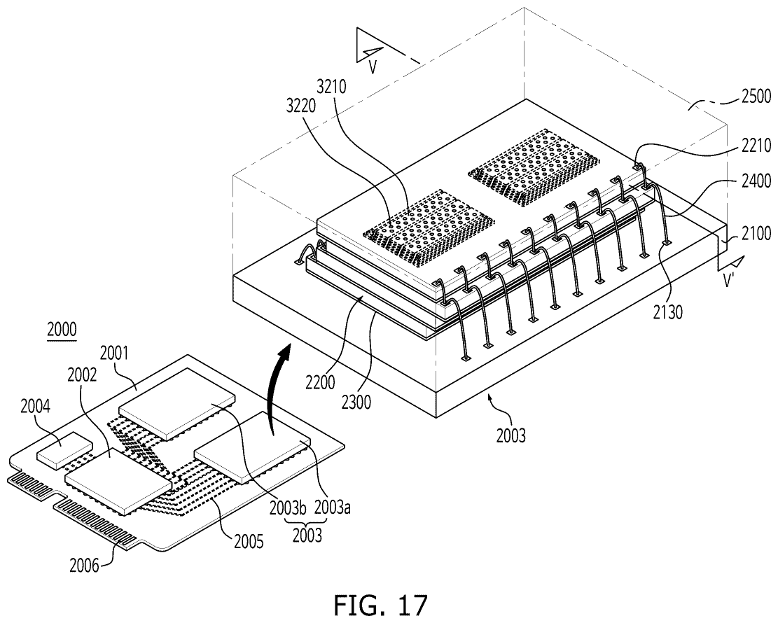

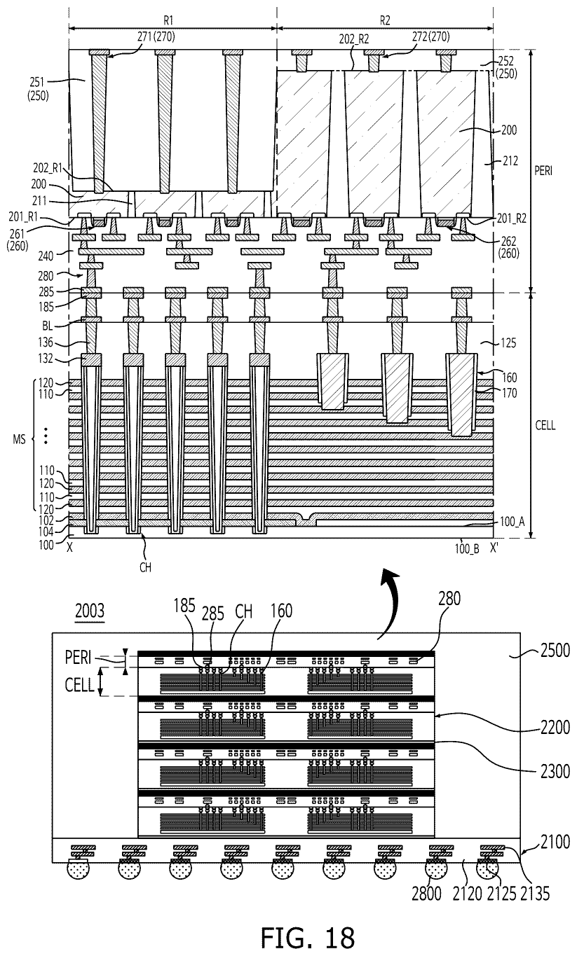

FIG. 17 is an example perspective view illustrating an electronic system including a semiconductor memory device according to some embodiments. FIG. 18 is a schematic cross-sectional view taken along line V-V′ of FIG. 17.

Referring to FIG. 17, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary according to the communication interface between the electronic system 2000 and the external host. In some embodiments, the electronic system 2000 may communicate with the external host according to interfaces such as Universal Serial Bus (USB), Peripheral Component Interconnect Express (PCI-Express), Serial Advanced Technology Attachment (SATA), and/or M-Phy for Universal Flash Storage (UFS). In some embodiments, the electronic system 2000 may be operated by the power supplied from the external host through the connector 2006. The electronic system 2000 may further include a power management integrated circuit (PMIC) that distributes power supplied from an external host to the controller 2002 and the semiconductor package 2003.

The main controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the main controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 of the plurality of semiconductor chips may include an input and output pad 2210. The input and output pad 2210 may correspond to the input and output pad 1101 of FIG. 16. Each of the semiconductor chips 2200 may include metal lines 3210 and channel structures 3220. Each of the semiconductor chips 2200 may include the semiconductor device described above with reference to FIGS. 1 and 9.

In some embodiments, the connection structure 2400 may be a bonding wire electrically connecting the input and output pad 2210 to the package upper pads 2130. Therefore, in each of the first and second semiconductor packages 2003a and 2003b, the semiconductor chips 2200 may be electrically connected to each other with the bonding wire method, and may be electrically connected to the package upper pads 2130 of the package substrate 2100. In some embodiments, in each of the first and second semiconductor packages 2003a and 2003b, instead of the bonding wire type connection structure 2400, the semiconductor chips 2200 may be electrically connected to each other through a connection structure including a through silicon via (TSV).

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some embodiments, the package substrate 2100 may be a printed circuit board. The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of the main substrate 2001 of the electronic system 2000 through conductive connections 2800, as illustrated in FIG. 17.

In the electronic system according to some embodiments, each of the semiconductor chips 2200 may include the semiconductor device described above with respect to FIGS. 1 and 9. For example, at least some of the semiconductor chips 2200 may include the peripheral circuit structure PERI disposed on the cell structure CELL. In another example, at least some of the semiconductor chips 2200 may include the cell structure CELL disposed on the peripheral circuit structure PERI. For example, the peripheral circuit structure PERI may include the peripheral circuit substrate 200 and the peripheral wiring structure 280 described above with reference to FIGS. 1 and 9. In addition, for example, the cell structure CELL may include the cell substrate 100, the mold structure MS, the channel structure CH, the bit line BL, the word line contact 160, and the contact spacer 170 described above using FIGS. 1 to 9. The peripheral circuit structure PERI and the cell structure CELL may be contacting or bonded to each other through the cell bonding pad 185 and the peripheral bonding pad 285.

Although the present disclosure has been described above by way of certain embodiments and drawings, the present invention is not limited thereto, and various changes and modifications can be made within the equivalent scope of the technical idea of the present disclosure and the claims to be described below by those of ordinary skill in the art.

1. A semiconductor memory device, comprising:
a cell structure including a cell wiring structure and a cell bonding pad electrically connected to the cell wiring structure; and
a peripheral circuit structure including a peripheral circuit substrate including a first surface and a second surface facing the first surface, a plurality of peripheral circuit elements disposed on the first surface of the peripheral circuit substrate, a peripheral wiring structure electrically connected to the plurality of peripheral circuit elements, and a peripheral bonding pad electrically connected to the peripheral wiring structure and in contact with the cell bonding pad,
wherein the plurality of peripheral circuit elements includes a plurality of first peripheral circuit elements disposed in a first region of the peripheral circuit substrate and a plurality of second peripheral circuit elements disposed in a second region of the peripheral circuit substrate,
wherein a thickness of the second region of the peripheral circuit substrate is greater than a thickness of the first region of the peripheral circuit substrate in a first direction,
wherein the first surface of the peripheral circuit substrate extends in a second direction, and
wherein the first direction intersects the second direction.

2. The semiconductor memory device according to claim 1, wherein
a first voltage is applied to the plurality of first peripheral circuit elements, and
a second voltage higher than the first voltage is applied to the plurality of second peripheral circuit elements.

3. The semiconductor memory device according to claim 1, wherein
each of the plurality of first peripheral circuit elements includes a first gate insulation film and a first gate electrode,
each of the plurality of second peripheral circuit elements includes a second gate insulation film and a second gate electrode,
a length of the second gate insulation film is longer than a length of the first gate insulation film in the second direction, and
a length of the second gate electrode is longer than a length of the first gate electrode in the second direction.

4. The semiconductor memory device according to claim 1,
wherein the peripheral circuit structure includes:
a first element isolation film in the first region of the peripheral circuit substrate in the first direction and separating adjacent first peripheral circuit elements of the plurality of first peripheral circuit elements; and
a second element isolation film in the second region of the peripheral circuit substrate in the first direction and separating adjacent second peripheral circuit elements of the plurality of second peripheral circuit elements, and
wherein a length of the second element isolation film in the first direction is longer than a length of the first element isolation film in the first direction.

5. The semiconductor memory device according to claim 4,
wherein the first element isolation film includes a first base surface coplanar with a first surface of the first region,
wherein the second element isolation film includes a second base surface coplanar with a first surface of the second region, and
wherein a width of the second base surface is greater than a width of the first base surface in the second direction.

6. The semiconductor memory device according to claim 5, wherein a width of the second element isolation film decreases in the second direction as it approaches a second surface of the second region along the first direction.

7. The semiconductor memory device according to claim 5,
wherein a width of the first element isolation film decreases in the second direction toward a second surface of the first region along the first direction, and
wherein the second element isolation film includes:
a first portion overlapping with the first element isolation film in the second direction and having a width decreasing in the second direction as a distance from the first surface of the second region increases in the first direction; and
a second portion in contact with the first portion and having a width increasing in the second direction toward a second surface of the second region along the first direction.

8. The semiconductor memory device according to claim 7,
wherein the second portion includes a third base surface coplanar with the second surface of the second region, and
wherein an angle between a side surface of the second portion and the third base surface is less than an angle between a side surface of the first portion and the second base surface.

9. The semiconductor memory device according to claim 1, wherein a second surface of the first region includes a first inclined surface and a second inclined surface which are inclined such that a width in the second direction decreases toward a second surface of the second region along the first direction.

10. The semiconductor memory device according to claim 9, wherein an angle between the first inclined surface or the second inclined surface and a first surface of the first region is from 53 to 56 degrees.

11. The semiconductor memory device according to claim 4,
wherein the peripheral circuit structure further includes a first peripheral insulation layer disposed on the first region of the peripheral circuit substrate and in contact with the first element isolation film, the first peripheral insulation layer having two opposing side surfaces, and
wherein each of the two opposing side surfaces of the first peripheral insulation layer includes a respective section inclined so as to diverge away from each other toward the second surface of the peripheral circuit substrate along the first direction.

12. The semiconductor memory device according to claim 11,
wherein the peripheral circuit structure further includes a second peripheral insulation layer disposed on the second region of the peripheral circuit substrate and in contact with the second element isolation film, and
wherein a thickness of the first peripheral insulation layer in the first direction is greater than a thickness of the second peripheral insulation layer in the first direction.

13. The semiconductor memory device according to claim 1, wherein the peripheral circuit structure further includes a first body contact in contact with a second surface of the first region and a second body contact in contact with a second surface of the second region.

14. A semiconductor memory device, comprising:
a cell structure including a cell wiring structure and a cell bonding pad electrically connected to the cell wiring structure; and
a peripheral circuit structure stacked on an upper surface of the cell structure in a first direction,
wherein the peripheral circuit structure includes:
a peripheral circuit substrate with a first surface and a second surface opposite to the first surface, the peripheral circuit substrate including a first region and a second region disposed in a second direction intersecting the first direction;
a first peripheral circuit element disposed on the first region and a second peripheral circuit element disposed on the second region;
a peripheral wiring structure electrically connected to the first peripheral circuit element and the second peripheral circuit element; and
a peripheral bonding pad electrically connected to the peripheral wiring structure and contacting the cell bonding pad, and
wherein a first surface of the first region and a first surface of the second region are coplanar with each other, and a second surface of the second region is positioned at a higher level in the first direction than a second surface of the first region.

15. The semiconductor memory device according to claim 14,
wherein the peripheral circuit structure further includes:
a first element isolation film in the first region of the peripheral circuit substrate in the first direction; and
a second element isolation film in the second region of the peripheral circuit substrate in the first direction, and
wherein a length of the second element isolation film in the first direction is greater than a length of the first element isolation film in the first direction.

16. The semiconductor memory device according to claim 15,
wherein a lower surface of the first element isolation film is positioned at the same level in the first direction as the first surface of the first region, and an upper surface of the first element isolation film is positioned at the same level in the first direction as the second surface of the first region, and
wherein a lower surface of the second element isolation film is positioned at the same level in the first direction as the first surface of the second region, and an upper surface of the second element isolation film is positioned at the same level in the first direction as the second surface of the second region.

17. The semiconductor memory device according to claim 15,
wherein the second element isolation film includes:
a first portion overlapping with the first element isolation film in the second direction; and
a second portion in contact with the first portion at a higher level in the first direction than the first portion, and
wherein a width of the second portion in the second direction is greater than a width of the first portion in the second direction.

18. The semiconductor memory device according to claim 15,
wherein the peripheral circuit structure further includes a first body contact in contact with the second surface of the first region and a second body contact in contact with the second surface of the second region, and
wherein a length of the first body contact in the first direction is greater than a length of the second body contact in the first direction.

19. The semiconductor memory device according to claim 15,
wherein the peripheral circuit structure further includes:
a first peripheral insulation layer disposed on the first region of the peripheral circuit substrate and in contact with the first element isolation film; and
a second peripheral insulation layer disposed on the second region of the peripheral circuit substrate and in contact with the second element isolation film is further included, and
wherein an upper surface of the first peripheral insulation layer is positioned at the same level in the first direction as an upper surface of the second peripheral insulation layer, and a lower surface of the first peripheral insulation layer is positioned at a lower level in the first direction than a lower surface of the second peripheral insulation layer.

20. An electronic system, comprising:
a main substrate;
a semiconductor memory device stacked on the main substrate; and
a controller on the main substrate, the controller electrically connected to the semiconductor memory device,
wherein the semiconductor memory device includes:
a cell structure including a cell wiring structure and a cell bonding pad electrically connected to the cell wiring structure; and
a peripheral circuit structure including a peripheral circuit substrate including a first surface and a second surface facing the first surface, a plurality of peripheral circuit elements disposed on the first surface of the peripheral circuit substrate, a peripheral wiring structure electrically connected to the plurality of peripheral circuit elements, and a peripheral bonding pad electrically connected to the peripheral wiring structure and in contact with the cell bonding pad,
wherein the plurality of peripheral circuit elements includes a plurality of first peripheral circuit elements to which a first voltage is applied and a plurality of second peripheral circuit elements to which a second voltage higher than the first voltage is applied,
wherein the peripheral circuit substrate includes a first region in which the plurality of first peripheral circuit elements are disposed and a second region in which the plurality of second peripheral circuit elements are disposed,
wherein a thickness of the second region of the peripheral circuit substrate is greater than a thickness of the first region of the peripheral circuit substrate in a first direction, the first surface of the peripheral circuit substrate extends in a second direction, and
wherein the first direction intersects the second direction.
